(19) United States
(12) Patent Application Publication
(10) Pub. No.: US 2026/0164780 A1
(43) Pub. Date: Jun. 11, 2026

(54) SEMICONDUCTOR STRUCTURE WITH STACKED TRANSISTORS

(71) Applicant: TAIWAN SEMICONDUCTOR MANUFACTURING COMPANY, LTD., Hsinchu (TW)

(72) Inventors: Meng-Yu LIN, New Taipei City (TW); Mahaveer Sathaiya DHANYAKUMAR, Hsinchu City (TW); Huan-Sheng WEI, Taipei City (TW); Chun-Fu CHENG, Hsinchu County (TW)

(73) Assignee: TAIWAN SEMICONDUCTOR MANUFACTURING COMPANY, LTD., Hsinchu (TW)

(21) Appl. No.: 18/970,253

(22) Filed: Dec. 5, 2024

(51) Int. Cl. H01L 21/02

(52) U.S. Cl. CPC H10D 84/851; H10D 84/0167; H10D 84/017; H10D 84/02

(57) ABSTRACT

A method includes following steps. 2D semiconductor nanostructures are formed arranged one above another. Each of the 2D semiconductor nanostructures has a 2D semiconductor material. First source/drain regions are formed at opposite regions of a first subset of the 2D semiconductor nanostructures. Second source/drain regions are formed at opposite regions of a second subset of the plurality of 2D semiconductor nanostructures. The second source/drain regions are above the first source/drain regions. A gate electrode is formed over the 2D semiconductor nanostructures.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other. While existing CFET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates an example of a complementary field-effect transistor (CFET) schematic in a three-dimensional view, in accordance with some embodiments.

FIG. 1B illustrates the example of CFET schematic in a side view, in accordance with some embodiments.

FIGS. 2A-8B are three-dimensional views and cross-sectional views of a CFET device at various stages of manufacturing, in accordance with some embodiments of the present disclosure.

FIGS. 8C-8E illustrate cross-sectional views in subsequent processing after forming the gate electrodes, in accordance with some embodiments of the present disclosure.

FIGS. 9-11 are cross-sectional views of a CFET device at various stages of manufacturing, in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

To achieve higher device density, silicon-based complementary field effect transistors (CFETs) have been developed from silicon nanosheet-FETs, which include a stacked transistor structure. However, to mitigate short channel effects and maintain process consistency with the same channel material, the channel dimensions and gate lengths cannot be significantly scaled down, thereby limiting the reduction of cell size in the channel length direction. Additionally, the increased stack height associated with the n/p stacking structure poses challenges for process capability, particularly in achieving vertical connections in CFET.

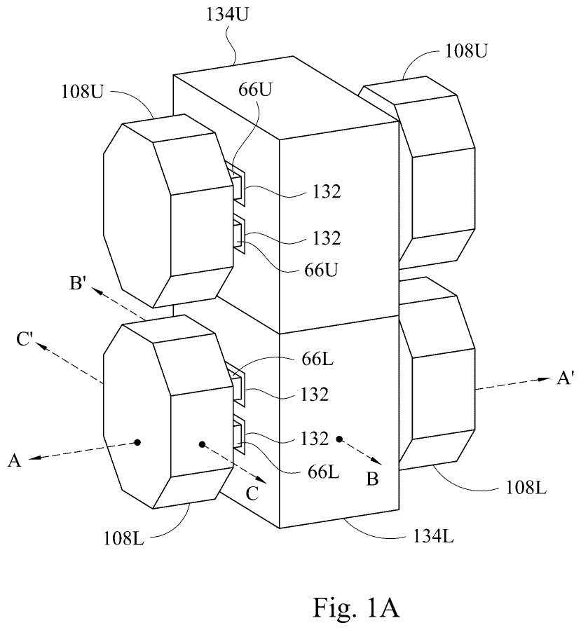

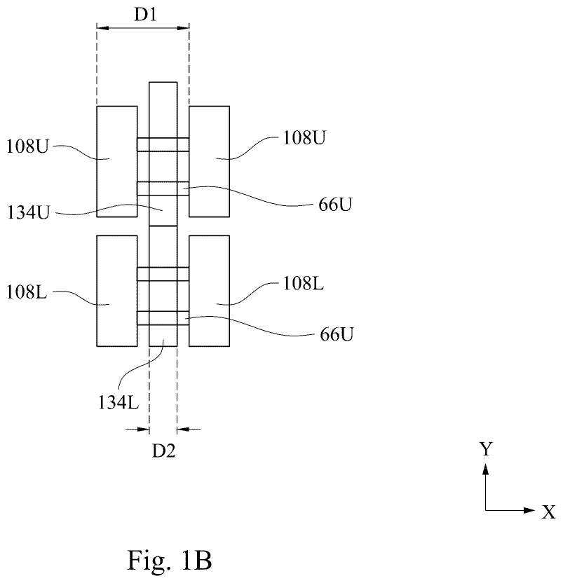

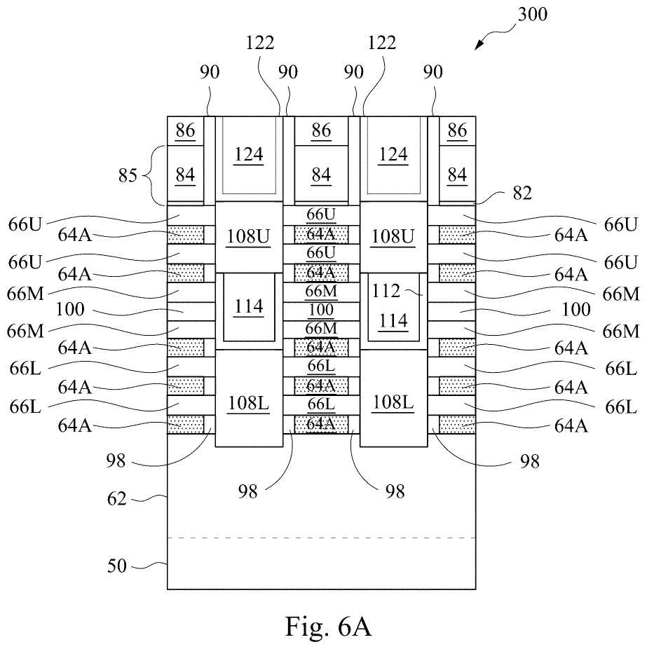

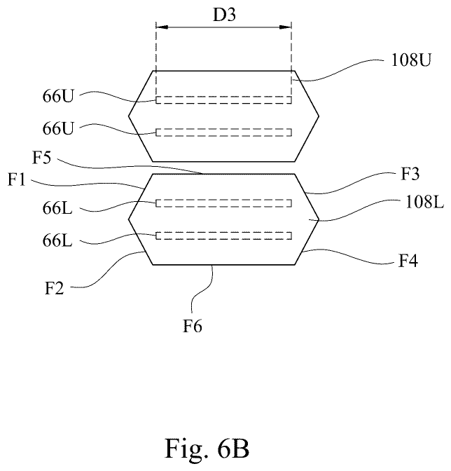

The present disclosure, in various embodiments, provides CFETs using two-dimensional (2D) semiconductor materials as their channel materials. 2D semiconductor channels exhibit superior gate control compared to silicon channels of the same dimensions, which allows for reduced gate lengths (e.g., gate length D2 illustrated in FIG. 1B) and widened sheet widths (e.g., sheet width D3 as illustrated in FIG. 6B). The thinner channel height of 2D semiconductor materials permits either an increased number of sheets at the same stack height or a reduced stack height with the same number of sheets. These advantages enable the 2D-CFET to achieve an increased device density.

FIGS. 1A and 1B illustrate an example of a 2D-CFET schematic, in accordance with some embodiments. FIG. 1A is a three-dimensional view and FIG. 1B is a side view, where some features of the 2D-CFET are omitted for illustration clarity.

The 2D-CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a 2D-CFET may include a lower nanostructure-FET of a first device type (e.g., n-type/p-type) and an upper nanostructure-FET of a second device type (e.g., p-type/n-type) that is opposite the first device type. Specifically, the 2D-CFET may include a lower PMOS transistor and an upper NMOS transistor, or the 2D-CFET may include a lower NMOS transistor and an upper PMOS transistor. Each of the nanostructure-FETs include 2D semiconductor nanostructures 66 (including lower 2D semiconductor nanostructures 66L and upper 2D semiconductor nanostructures 66U), where the 2D semiconductor nanostructures 66 act as channel regions (also referred to as channel layers, semiconductor channels regions, or semiconductor channel layers) for the nanostructure-FETs. The 2D semiconductor nanostructures 66 may be nanosheets, nanowires, or the like. The lower 2D semiconductor nanostructures 66L are for a lower nanostructure-FET and the upper 2D semiconductor nanostructures 66U are for an upper nanostructure-FET. A nanostructure isolation material (not explicitly illustrated in FIG. 1A, see 100 in FIG. 6A) may be used to separate and electrically isolate the upper 2D semiconductor nanostructures 66U from the lower 2D semiconductor nanostructures 66L.

Gate dielectrics 132 are along top surfaces, sidewalls, and bottom surfaces of the 2D semiconductor nanostructures 66. Gate electrodes 134 (including a lower gate electrode 134L and an upper gate electrode 134U) are over the gate dielectrics 132 and around the 2D semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer. Alternatively, a lower gate electrode 134L may be coupled to an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of 2D-CFETs, the schematic may also be referred to as stacking transistors or folding transistors.

As illustrated in FIG. 1B, by using the 2D semiconductor nanostructures 66 as channels of the 2D-CFETs, the horizontal dimension D1 of 2D-CFETs, or called contacted poly pitch (CPP), which extends in a channel length direction X of the 2D-CFETs can be significantly reduced compared to silicon-based CFETs that use silicon-based nanostructures. This dimension reduction is primarily attributed to the superior gate control offered by 2D semiconductor channels compared to silicon channels of the same dimensions. Consequently, this enhanced gate control allows for further scaling down of the horizontal dimension D1 in the channel length direction X, surpassing the dimension limitations of silicon-based CFETs.

FIG. 1A further illustrates reference cross-sections that are used in later figures. Cross-section A-A′ is parallel to a longitudinal axis of the 2D semiconductor nanostructures 66 of a CFET and in a direction of, for example, a current flow between the source/drain regions 108 of the 2D-CFET. Cross-section B-B′ is perpendicular to cross-section A-A′ and along a longitudinal axis of a gate electrode 134 of a 2D-CFET. Cross-section C-C′ is parallel to cross-section B-B′ and extends through the source/drain regions 108 of the 2D-CFETs. Subsequent figures refer to these reference cross-sections for clarity.

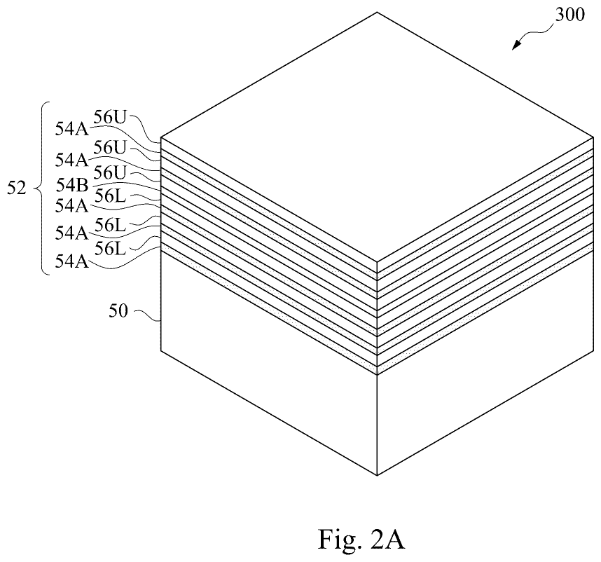

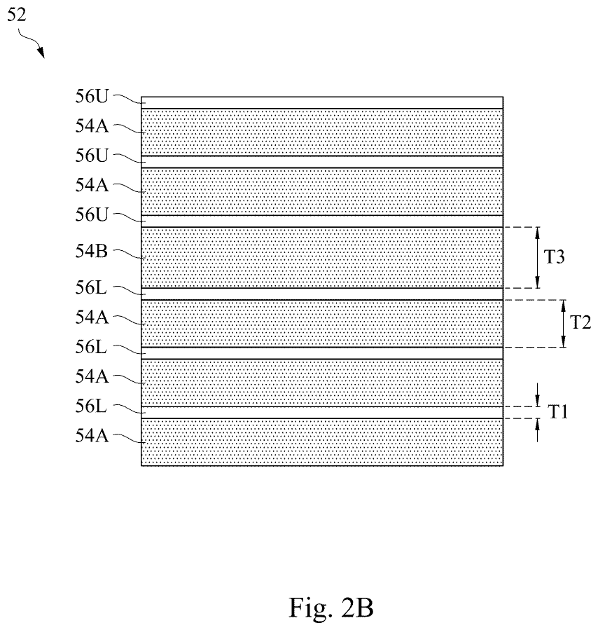

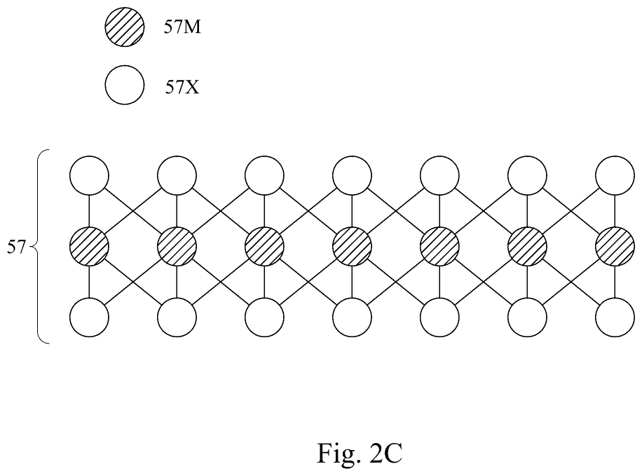

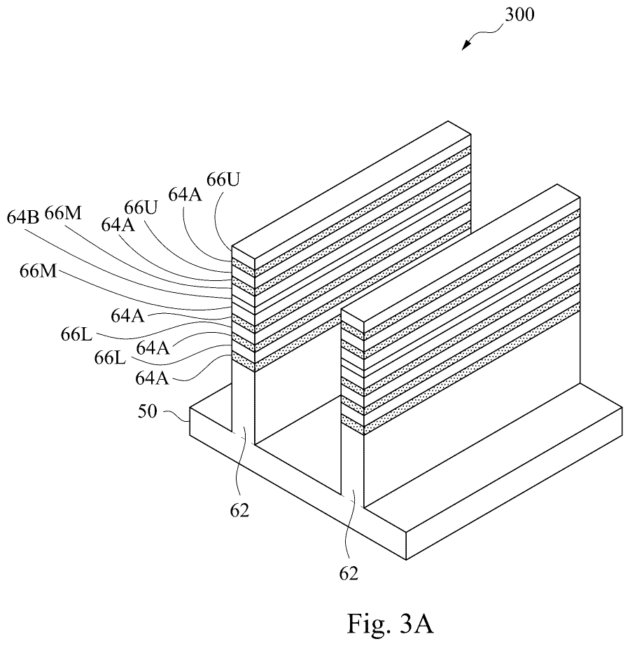

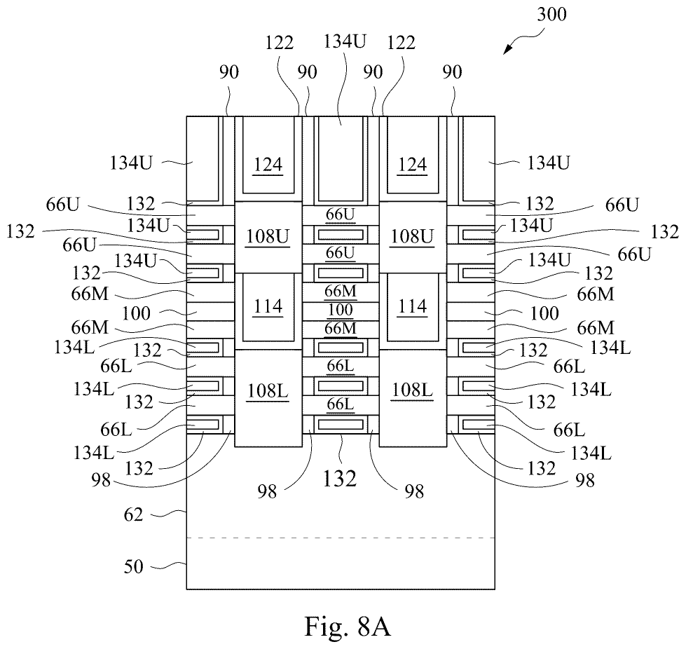

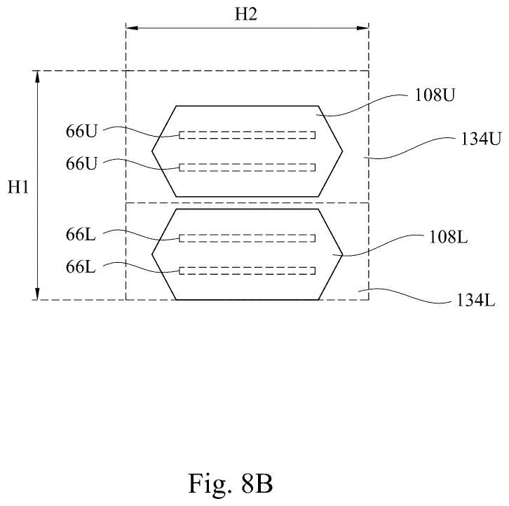

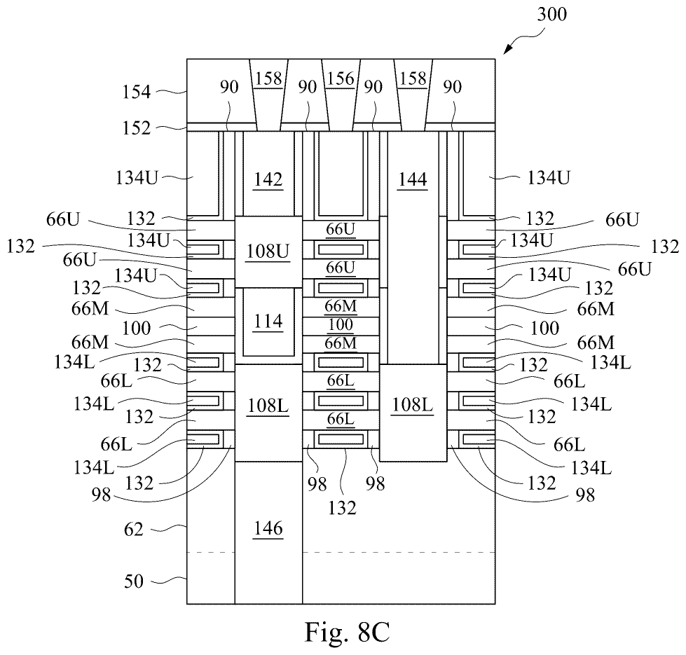

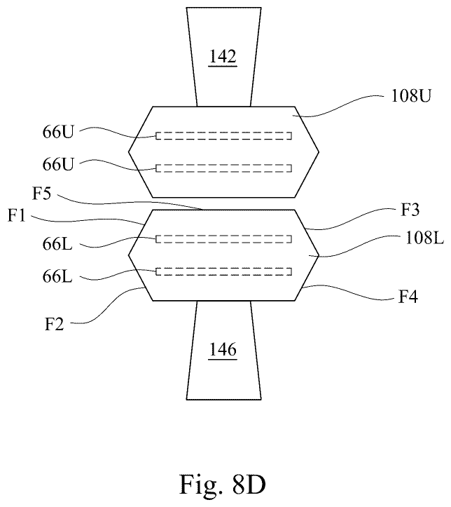

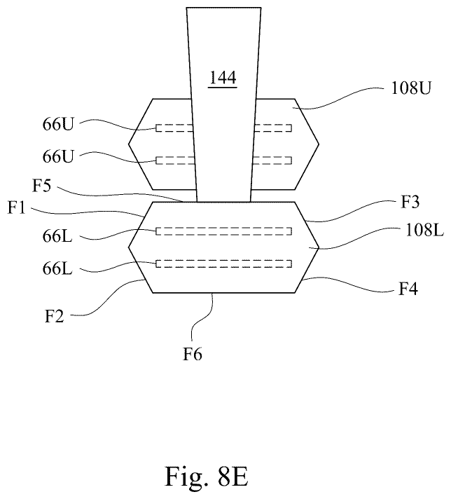

FIGS. 2A-8B are three-dimensional views and cross-sectional views of a CFET device 300 at various stages of manufacturing, in accordance with some embodiments of the present disclosure. FIGS. 2A, 3A, and 4 are three-dimensional views showing a similar three-dimensional view as FIG. 1A. FIGS. 2B, 3B 5, 6A, 7, and 8A illustrate cross-sectional views along a similar cross-section as reference cross-section A-A′ in FIG. 1A. FIGS. 6B and 8B illustrate cross-sectional views along a similar cross-section as reference cross-section C-C′ in FIG. 1A. FIG. 2C illustrates a schematic view of a mono-layer of an example 2D semiconductor material in accordance with some embodiments of the present disclosure.

In FIG. 2A, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and 2D semiconductor layers 56 (including lower 2D semiconductor layers 56L and upper 2D semiconductor layers 56U). The lower 2D semiconductor layers 56L and a subset of the first dummy layers 54A are disposed below the second dummy layer 54B. The upper 2D semiconductor layers 56U and another subset of the first dummy layers 54A are disposed above the second dummy layer 54B. As subsequently described in greater detail, the dummy layers 54 will be removed and the 2D semiconductor layers 56 will be patterned to form 2D channel regions of 2D-CFETs. Specifically, the lower 2D semiconductor layers 56L will be patterned to form 2D channel regions of the lower nanostructure-FETs of the 2D-CFETs, and the upper 2D semiconductor layers 56U will be patterned to form 2D channel regions of the upper nanostructure-FETs of the 2D-CFETs.

The multi-layer stack 52 is illustrated as including six of the dummy layers 54 and six of the 2D semiconductor layers 56. It is appreciated that the multi-layer stack 52 may include any number of the dummy layers 54 and the 2D semiconductor layers 56. Each dummy layer 54 of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. Following growth of each dummy layer 54, a 2D semiconductor layer 56 is then formed on each of the dummy layers 54. 2D semiconductor materials are usually few-layer thick and exist as stacks of strongly bonded layers with weak interlayer van der Waals attraction, allowing the layers to be mechanically or chemically exfoliated into individual, atomically thin layers. The 2D semiconductor materials are promising candidates of the channel, source, drain materials of transistors. Examples of 2D semiconductor materials include transition metal dichalcogenides (TMDs), layered III-VI chalcogenide, graphene, hexagonal Boron Nitride (h-BN), black phosphorus or the like. The 2D semiconductor may include one or more layers and can have a thickness within the range of about 0.5-100 nm in some embodiments. One advantageous feature of the few-layered 2D semiconductor is the high electron mobility value, which is within a range of about 50-1000 cm²/V-sec or even higher. It is understood that the bulk silicon, when cut to a low thickness (e.g., about 3 nm) comparable with a thickness of a 2D material film, may have its mobility degraded drastically.

In some embodiments as illustrated in FIG. 2B, each of the 2D semiconductor layers 56 has a thickness T1, each of the first dummy layers 54A has a thickness T2, and the second dummy layer 54B has a thickness T3. In some embodiments, the thickness T1 of the 2D semiconductor layer 56 is less than the thickness T2 of the first dummy layer 54A, and/or less than the thickness T3 of the second dummy layer 54B. This configuration allows for an increased number of 2D semiconductor layers 56 within a given stack height of the multi-layer stack 52, or alternatively, permits a reduction in the overall stack height of the multi-layer stack 52. In some embodiments, the ratio of the thickness T2 of the first dummy layer 54A to the thickness T1 of the 2D semiconductor layer 56 is greater than 2:1, 3:1, 4:1, 5:1, 6:1, 7:1, 8:1, 9:1, or 10:1. In some embodiments, the ratio of the thickness T3 of the second dummy layer 54B to the thickness T1 of the 2D semiconductor layer 56 is greater than 2:1, 3:1, 4:1, 5:1, 6:1, 7:1, 8:1, 9:1, 10:1, 11:1, or 12:1. In some embodiments, the thickness T3 of the second dummy layer 54B is greater than the thickness T2 of the first dummy layer 54A. Forming the second dummy layer 54B with a larger thickness allows the second dummy layer 54B to be more easily removed in subsequently processing. Additionally, the thicknesses T1 of different 2D semiconductor layers 56 may be different, depending on the fabrication process of each 2D semiconductor layer 56. Since the thickness T1 of the 2D semiconductor layer 56 depends on the total count of its monolayers 57, the thickness T1 of each 2D semiconductor layer 56 can be precisely controlled by adjusting the desired total count of monolayers 57 in each 2D semiconductor layer 56.

In some embodiments, each of the 2D semiconductor layers 56 is a transition metal dichalcogenide (TMD) material which has the formula MX₂, wherein M is a transition metal element such as titanium, vanadium, cobalt, nickel, zirconium, molybdenum, technetium, rhodium, palladium, hafnium, tantalum, tungsten, rhenium, iridium, platinum, and X is a chalcogen such as sulfur, selenium, or tellurium. Examples of dichalcogenide materials that are suitable for the 2D semiconductor layer 56 include WS₂, MoS₂, WSe₂, MoSe₂, MoTe₂, WTe₂, the like, or a combination thereof. However, any suitable transition metal dichalcogenide material may alternatively be used. Once formed, the transition metal dichalcogenide material is in a layered structure with a plurality of two-dimensional layers of the general form X-M-X, with the chalcogen atoms in two planes separated by a plane of metal atoms.

Each of the 2D semiconductor layers 56 may be a mono-layer or may include a few monolayers. FIG. 2C illustrates a schematic view of a monolayer 57 of an example 2D semiconductor material (e.g., TMD) in accordance with some example embodiments. In FIG. 2C, the one-molecule thick TMD material layer comprises transition metal atoms 57M and chalcogen atoms 57X. The transition metal atoms 57M may form a layer in a middle region of the one-molecule thick TMD material layer, and the chalcogen atoms 57X may form a first layer over the layer of transition metal atoms 57M, and a second layer underlying the layer of transition metal atoms 57M. The transition metal atoms 57M may be W atoms or Mo atoms, while the chalcogen atoms 57X may be S atoms, Se atoms, or Te atoms. In the example of FIG. 2C, each of the transition metal atoms 57M is bonded (e.g. by covalent bonds) to six chalcogen atoms 57X, and each of the chalcogen atoms 57X is bonded (e.g. by covalent bonds) to three transition metal atoms 57M. Throughout the description, the illustrated cross-bonded layers including one layer of transition metal atoms 57M and two layers of chalcogen atoms 57X in combination are referred to as a mono-layer 57 of TMD.

In some embodiments, the 2D semiconductor layers 56 are formed by using any suitable deposition techniques. For example, in some embodiments where the 2D semiconductor layers 56 are formed of WS₂, each 2D semiconductor layer 56 can be formed by using an inductively-coupled-plasma (ICP) CVD process with a tungsten-containing gas (e.g., WF₆) and a sulfur-containing gas (e.g., H₂S) as precursors. In some embodiments, each WS₂ layer may be deposited to have a final thickness in a range from about 0.5 nm to about 5 nm. The process conditions are controlled to achieve the desirable total count of monolayers 57 in a WS₂ layer.

In some other embodiments, each of the 2D semiconductor layers 56 are formed using exfoliation and taping method. For example, a 2D semiconductor layer can be grown on another crystalline substrate by using suitable deposition techniques, and the 2D semiconductor layer is then transferred onto the dummy layer 54 (i.e., first dummy layer 54A or second dummy layer 54B). For example, the 2D semiconductor layer grown on the crystalline substrate can be covered with a protection film (e.g., PMMA) and a thermal release tape, and then the 2D semiconductor layer is mechanically or chemically exfoliated from the crystalline substrate and then transferred onto the dummy layer 54. Next, the thermal release tape can be removed by, for example, baking the thermal release tape, so that the thermal release tape loses adhesiveness. Next, the protection film can be removed by, for example, etching or dissolving. After removal of the protection film, a 2D semiconductor layer 56 remains on the dummy layer 54, and is ready for deposition of a next dummy layer 54.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. As such, the material of the second dummy layer 54B may be removed at a faster rate than the material of the first dummy layers 54A in subsequent processing.

In some embodiments, the lower 2D semiconductor layers 56L and the upper 2D semiconductor layers 56U may be formed of the same 2D semiconductor material, or may be formed of different 2D semiconductor materials. The 2D semiconductor material(s) of the 2D semiconductor layers 56 have a high etching selectivity to the non-2D semiconductor materials of the dummy layers 54. As such, the non-2D semiconductor materials of the dummy layers 54 may be removed at a faster rate than the 2D semiconductor material of the 2D semiconductor layers 56 in subsequent processing.

In some embodiments, the first dummy layers 54A are formed of silicon-germanium with a first germanium atomic percentage, the second dummy layer 54B is formed of silicon-germanium with a second germanium atomic percentage that is higher than the first germanium atomic percentage. The difference between the second germanium atomic percentage and the first germanium atomic percentage may be higher than about 30 percent, and may be in the range between about 36 percent and about 60 percent. The higher germanium atomic percentage allows the second dummy layer 54B to be etched at a faster rate than the first dummy layers 54A, and allow the second dummy layer 54B to be completed removed during a subsequent etching process, as discussed hereinafter.

In FIG. 3A, fins 62 are formed in the substrate 50 and nanostructures 64, 66 (including first dummy nanostructures 64A, second dummy nanostructures 64B, lower 2D semiconductor nanostructures 66L, middle 2D semiconductor nanostructures 66M, and upper 2D semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower 2D semiconductor nanostructures 66L from some of the lower semiconductor layers 56L, the upper 2D semiconductor nanostructures 66U from some of the upper 2D semiconductor layers 56U, and the middle 2D semiconductor nanostructures 66M from some of the lower 2D semiconductor layers 56L and some of the upper 2D semiconductor layers 56U. The first dummy nanostructures 64A and the second dummy nanostructures 64B may further be collectively referred to as the dummy nanostructures 64. The lower 2D semiconductor nanostructures 66L and the upper 2D semiconductor nanostructures 66U may further be collectively referred to as the 2D semiconductor nanostructures 66.

As subsequently described in greater detail, the dummy nanostructures 64 will be removed to form channel regions of CFETs. Specifically, the lower 2D semiconductor nanostructures 66L will act as channel regions for lower nanostructure-FETs of the 2D-CFETs. Additionally, the upper 2D semiconductor nanostructures 66U will act as channel regions for upper nanostructure-FETs of the 2D-CFETs.

In some embodiments as illustrated in FIG. 3B, each of the 2D semiconductor nanostructures 66 has a thickness T4, each of the first dummy nanostructures 64A has a thickness T5, and the second dummy nanostructure 64B has a thickness T6. In some embodiments, the thickness T4 of the 2D semiconductor nanostructure 66 is less than the thickness T5 of the first dummy nanostructure 64A, and/or less than the thickness T6 of the second dummy nanostructure 64B. This configuration allows for an increased number of 2D semiconductor nanostructures 66 within a given stack height, or alternatively, permits a reduction in the overall stack height. In some embodiments, the ratio of the thickness T5 of the first dummy nanostructure 64A to the thickness T4 of the 2D semiconductor nanostructure 66 is greater than 2:1, 3:1, 4:1, 5:1, 6:1, 7:1, 8:1, 9:1, or 10:1. In some embodiments, the ratio of the thickness T6 of the second dummy nanostructure 64B to the thickness T4 of the 2D semiconductor nanostructure 66 is greater than 2:1, 3:1, 4:1, 5:1, 6:1, 7:1, 8:1, 9:1, 10:1, 11:1, or 12:1. In some embodiments, the thickness T6 of the second dummy nanostructure 64B is greater than the thickness T5 of the first dummy nanostructure 64A. Forming the second dummy nanostructure 64B with a larger thickness allows the second dummy nanostructure 64B to be more easily removed in subsequently processing. Additionally, the thicknesses T4 of different 2D semiconductor nanostructure 66 may be different, depending on the fabrication process of each 2D semiconductor layer. Since the thickness T4 of the 2D semiconductor nanostructure 66 depends on the total count of its monolayers 57, as illustrated in FIG. 2C, the thickness T4 of each 2D semiconductor nanostructure 66 can be precisely controlled by adjusting the desired total count of monolayers 57 in each 2D semiconductor nanostructure 66.

The middle 2D semiconductor nanostructures 66M are the 2D semiconductor nanostructures 66 that are directly above/below (e.g., in contact with) the second dummy nanostructures 64B. Depending on the heights of subsequently formed source/drain regions, the middle 2D semiconductor nanostructures 66M may or may not adjoin any source/drain regions and may or may not act as functional channel regions for the 2D-CFETs. The second dummy nanostructures 64B will be subsequently replaced with isolation structures. The isolation structures and the middle 2D semiconductor nanostructures 66M may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in cross-section view.

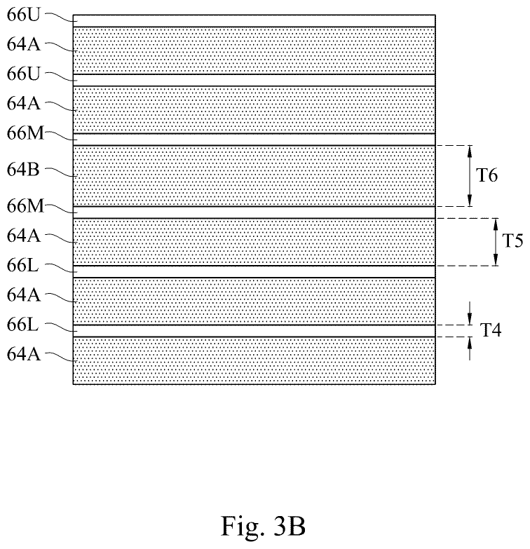

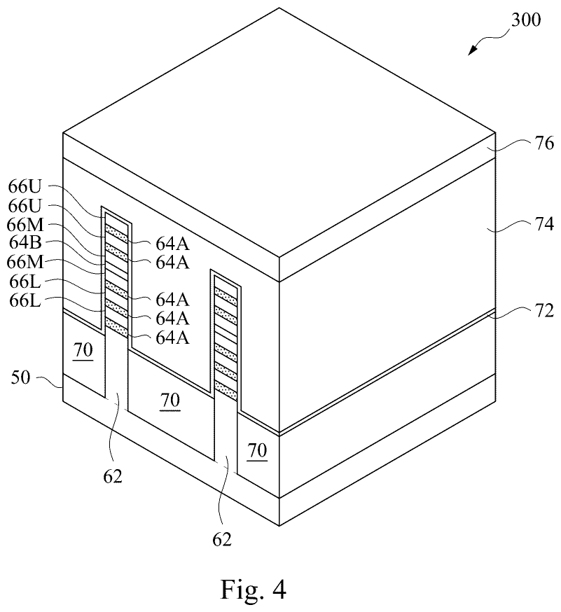

In FIG. 4, isolation regions 70 are formed adjacent to the fins 62. The isolation regions 70 may be formed by depositing an insulating material over the substrate 50, the fins 62, and nanostructures 64, 66, and between adjacent fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 64, 66. Although the insulating material is illustrated as a single layer, some embodiments may utilize multiple layers. For example, in some embodiments a liner (not separately illustrated) may first be formed along a surface of the substrate 50, the fins 62, and the nanostructures 64, 66. Thereafter, a fill material, such as one of the previously described insulating materials may be formed over the liner.

A removal process is then applied to the insulating material to remove excess insulating material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulating material are level after the planarization process is complete.

The insulating material is then recessed to form the isolation regions 70. The insulating material is recessed such that upper portions of the fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the fins 62 and the nanostructures 64, 66). For example, an oxide removal using, for example, dilute hydrofluoric (dHF) acid may be used.

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), or the like. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

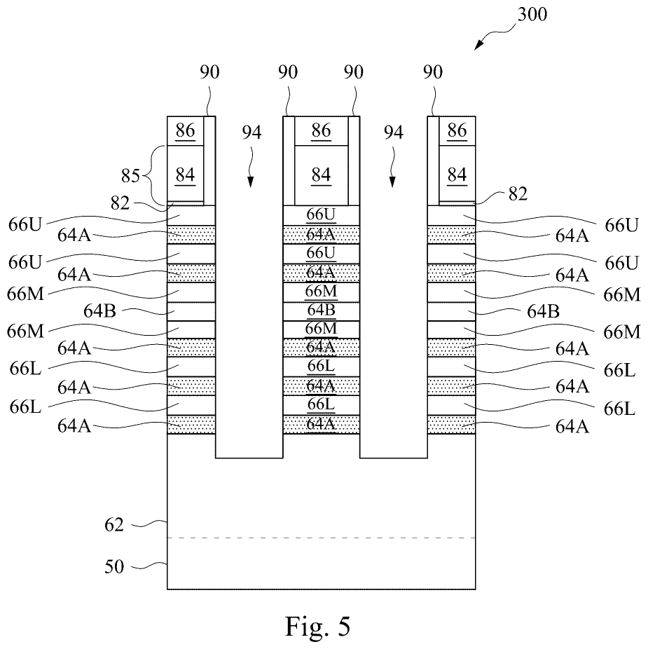

Next, in FIG. 5, the mask layer 76 is patterned using acceptable photolithography and etching techniques to form masks 86. The pattern of the masks 86 is then transferred to the dummy gate layer 74 and to the dummy dielectric layer 72 to form dummy gates 84 and dummy dielectrics 82, respectively. The dummy gates 84 and the dummy dielectrics 82 are collectively referred to as dummy gate stacks 85. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In FIG. 5, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 84 (thus forming the gate spacers 90). Fin spacers may also be formed as part of forming the gate spacers 90.

Source/drain recesses 94 are formed in the nanostructures 64, 66, and the fins 62. Epitaxial source/drain regions will be subsequently formed in the source/drain recesses 94. The source/drain recesses 94 may extend through the nanostructures 64, 66 and into the fins 62. The fins 62 may be etched such that bottom surfaces of the source/drain recesses 94 are disposed above, below, or level with the top surfaces of the isolation regions 70. The source/drain recesses 94 may be formed by etching the nanostructures 64, 66, and the substrate 50 using anisotropic etching processes, such as RIE, NBE, or the like. The gate spacers 90 and the dummy gates 84 mask portions of the nanostructures 64, 66, and the fins 62 during the etching processes used to form the source/drain recesses 94. A single etch process or multiple etch processes may be used to etch each layer of the nanostructures 64, 66, and the fins 62. Timed etch processes may be used to stop the etching of the source/drain recesses 94 after the source/drain recesses 94 reach a desired depth.

Next, in FIG. 6A, inner spacers 98 and dielectric isolation layers 100 are formed. Forming inner spacers 98 and dielectric isolation layers 100 (also referred to as isolation structures 100) may include an etching process that laterally etches the dummy nanostructures 64A and removes the dummy nanostructure 64B. The etching process may be isotropic and may be selective to the material of the dummy nanostructures 64, so that the dummy nanostructures 64 are etched at a faster rate than the 2D semiconductor nanostructures 66. The etching process may also be selective to the material of the dummy nanostructures 64B, so that the dummy nanostructures 64B are etched at a faster rate than the dummy nanostructures 64A. In this manner, the dummy nanostructures 64B may be completely removed from between the middle 2D semiconductor nanostructures 66M without completely removing the dummy nanostructures 64A. In some embodiments where the dummy nanostructures 64B are formed of germanium or silicon germanium with a high germanium atomic percentage, the dummy nanostructures 64A are formed of silicon germanium with a low germanium atomic percentage, and the 2D semiconductor nanostructures 66 are formed of 2D semiconductor material (e.g., TMD) free from germanium, the etch process may comprise a dry etch process using chlorine gas, with or without a plasma. Because the dummy gate stacks 85 wrap around sidewalls of the 2D semiconductor nanostructures 66 (see FIG. 4), the dummy gate stacks 85 may support the upper 2D semiconductor nanostructures 66U so that the upper 2D semiconductor nanostructures 66U do not collapse upon removal of the dummy nanostructures 64B. Further, although sidewalls of the dummy nanostructures 64A are illustrated as being straight after the etching, the sidewalls may be concave or convex.

Inner spacers 98 are formed on sidewalls of the recessed dummy nanostructures 64A, and dielectric isolation layers 100 are formed between the middle 2D semiconductor nanostructures 66M. As subsequently described in greater detail, source/drain regions will be subsequently formed in the source/drain recesses 94, and the dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as the etch processes used to form gate structures. Dielectric isolation layers 100, on the other hand, are used to isolate the upper 2D semiconductor nanostructures 66U (collectively) from the lower 2D semiconductor nanostructures 66L (collectively). Further, the middle 2D semiconductor nanostructures 66M and the dielectric isolation layers 100 may define the boundaries of the lower nanostructure-FETs and the upper nanostructure-FETs.

The inner spacers 98 and the dielectric isolation layers 100 may be formed by conformally depositing an insulating material in the source/drain recesses 94, on sidewalls of the dummy nanostructures 64A, and between the middle 2D semiconductor nanostructures 66M, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 64A (thus forming the inner spacers 98) and has portions remaining in between the middle 2D semiconductor nanostructures 66M (thus forming the dielectric isolation layers 100).

As also illustrated by FIG. 6A, lower epitaxial source/drain regions 108L and upper epitaxial source/drain regions 108U are formed. The lower epitaxial source/drain regions 108L are formed in the lower portions of the source/drain recesses 94. The lower epitaxial source/drain regions 108L are in contact with the lower 2D semiconductor nanostructures 66L and are not in contact with the upper 2D semiconductor nanostructures 66U. Inner spacers 98 electrically insulate the lower epitaxial source/drain regions 108L from the dummy nanostructures 64A, which will be replaced with replacement gates in subsequent processes.

The lower epitaxial source/drain regions 108L are epitaxially grown from 2D semiconductor materials (e.g., TMD) of the lower 2D semiconductor nanostructures 66L, and have a conductivity type that is suitable for the device type (p-type or n-type) of the lower nanostructure-FETs. When lower epitaxial source/drain regions 108L are n-type source/drain regions, the respective material may include, by way of example and not limitation, molybdenum disulfide (MoS₂) or tungsten disulfide (WS₂). These materials can be doped to achieve n-type conductivity by doping an n-type dopant species including elements such as rhenium (Re) or niobium (Nb) during the epitaxial growth process. For instance, Re can be doped into MoS₂ to substitute Mo in MoS₂, providing extra electrons that contribute to n-type conductivity. When lower epitaxial source/drain regions 108L are p-type source/drain regions, the respective material may include, by way of example and not limitation, tungsten diselenide (WSe₂) or molybdenum diselenide (MoSe₂). These materials can be doped to achieve p-type conductivity by doping a p-type dopant species including elements such as niobium (Nb) during the epitaxial growth process. For example, Nb can be doped into WSe₂ to substitute W in WSe₂, creating holes that contribute to p-type conductivity. The lower epitaxial source/drain regions 108L may be in-situ doped, and may be, or may not be, implanted with the corresponding p-type or n-type dopants. During the epitaxy of the lower epitaxial source/drain regions 108L, the upper 2D semiconductor nanostructures 66U may be masked to prevent undesired epitaxial growth on the upper 2D semiconductor nanostructures 66U. After the lower epitaxial source/drain regions 108L are grown, the masks on the upper 2D semiconductor nanostructures 66U may then be removed.

A first contact etch stop layer (CESL) 112 and a first interlayer dielectric (ILD) 114 are formed over the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. An anisotropic etching process is then performed to remove the portions of the first CESL 112 higher than the recessed first ILD 114. After the recessing, the sidewalls of the upper 2D semiconductor nanostructures 66U are exposed.

Upper epitaxial source/drain regions 108U are then formed in the upper portions of the source/drain recesses 94. The upper epitaxial source/drain regions 108U may be epitaxially grown from exposed surfaces of the upper 2D semiconductor nanostructures 66U. The materials of upper epitaxial source/drain regions 108U may be selected from the same candidate group of materials for forming lower source/drain regions 108L, depending on the desired conductivity type of upper epitaxial source/drain regions 108U. The conductivity type of the upper epitaxial source/drain regions 108U may be opposite the conductivity type of the lower epitaxial source/drain regions 108L, which allows for forming a stacked CFET structure including vertically stacked p-type field effect transistor (PFET) and n-type field effect transistor (NFET). For example, the upper epitaxial source/drain regions 108U may be oppositely doped from the lower epitaxial source/drain regions 108L. For example, a dopant species in the upper epitaxial source/drain regions 108U is different from a dopant species in the lower epitaxial source/drain regions 108L. For example, when the upper epitaxial source/drain regions 108U are doped with an n-type dopant species, the lower epitaxial source/drain regions 108L are doped with a p-type dopant species; and when the upper epitaxial source/drain regions 108U are doped with a p-type dopant species, the lower epitaxial source/drain regions 108L are doped with an n-type dopant species.

In some embodiments, the upper epitaxial source/drain regions 108U are epitaxially grown from 2D semiconductor materials (e.g., TMD) of the upper 2D semiconductor nanostructures 66U, and have a conductivity type that is suitable for the device type (p-type or n-type) of the upper nanostructure-FETs. When upper epitaxial source/drain regions 108U are n-type source/drain regions, the respective material may include, by way of example and not limitation, molybdenum disulfide (MoS₂) or tungsten disulfide (WS₂). These materials can be doped to achieve n-type conductivity by doping a dopant species including elements such as rhenium (Re) or niobium (Nb) during the epitaxial growth process. For instance, Re can be doped into MoS₂ to substitute Mo in MoS₂, providing extra electrons that contribute to n-type conductivity. When upper epitaxial source/drain regions 108U are p-type source/drain regions, the respective material may include, by way of example and not limitation, tungsten diselenide (WSe₂) or molybdenum diselenide (MoSe₂). These materials can be doped to achieve p-type conductivity by doping a dopant species including elements such as niobium (Nb) during the epitaxial growth process. For example, Nb can be doped into WSe₂ to substitute W in WSe₂, creating holes that contribute to p-type conductivity. The upper epitaxial source/drain regions 108U may be in-situ doped, and may be, or may not be, implanted with the corresponding p-type or n-type dopants. In some embodiments, the lower and upper source/drain regions 108L and 108U are metal materials (e.g., tungsten or ruthenium) directly in contact with the end surfaces of the semiconductor nanostructures 66L and 66U.

In some embodiments, as illustrated in the cross-sectional view of FIG. 6B, the lower epitaxial source/drain region108L has facets F1, F2, F3, and F4 which extend laterally outward beyond sidewalls of the nanostructures 64 and 66. In some embodiments, the facets F1 and T3 are up-slant facets facing upwards, and the facets F2 and F4 are down-slant facets facing downwards. In some embodiments, the lower epitaxial source/drain region 108L has a top horizontal facet F5 connecting the up-slant faces F1 and F3, and a bottom horizontal facet F6 connecting the down-slant facets F2 and F4. In some embodiments, the up-slant facets F1, F3, and down-slant facets F2 and F4 are smaller than the top and bottom horizontal facets F5 and F6, because the 2D semiconductor nanostructures 66L have their thicknesses significantly less than their widths. Similarly, the upper epitaxial source/drain region 108U has two up-slant facets facing upwards, two down-slant facets facing downwards, a top horizontal facet connecting the up-slant facets, and a bottom horizontal facet connecting the down-slant facets. Moreover, the up-slant facets and down-slant facets of the upper epitaxial source/drain region 108U are smaller than the top and bottom horizontal facets, because the 2D semiconductor nanostructures 66U have their thicknesses significantly less than their widths.

In FIG. 6A, after the epitaxial source/drain regions 108U are formed, a second CESL 122 and a second ILD 124 are formed. The materials and the formation methods may be similar to the materials and the formation methods of first CESL 112 and first ILD 114, respectively, and are not discussed in detail herein. The formation process may include depositing the layers for the second CESL 122 and the second ILD 124, and performing a planarization process to remove the excess portion of the corresponding layers. After the planarization process, top surfaces of the second ILD 124, the second CESL 122, the gate spacers 90, and the masks 86 are coplanar (within process variations). The planarization process may leave masks 86 unremoved (as shown), or may remove the masks 86, in which case the top surface of the second ILD 124 is level with the top surface of the dummy gate stacks 85.

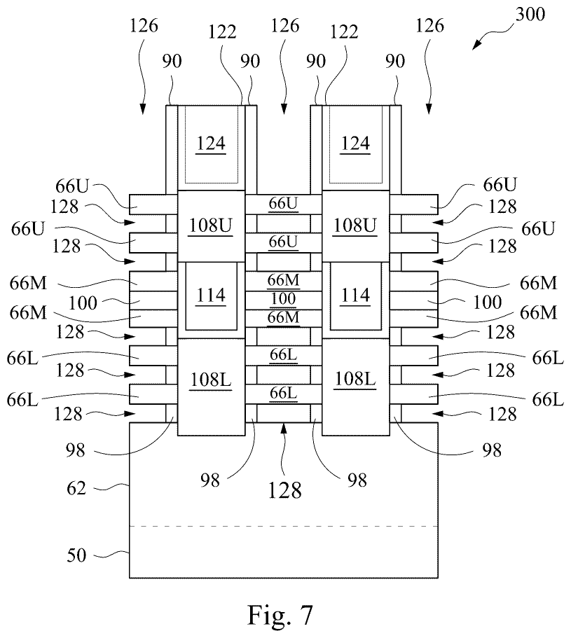

Next, in FIG. 7, the mask 86 (if not removed already) is removed, e.g., by a CMP process. Next, the dummy gate stacks 85 are removed in one or more etching steps, so that recesses 126 are formed between the gate spacers 90. In some embodiments, the dummy gates 84 and the dummy dielectrics 82 are removed by an anisotropic dry etch process. For example, the etching process may include a dry etch process using reaction gas(es) that selectively etch the material of the dummy gates 84. Each of the recesses 126 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings 128 in regions between the 2D semiconductor nanostructures 66. The remaining portions of the first dummy nanostructures 64A can be removed by any acceptable etch process that selectively etches the material of the first dummy nanostructures 64A at a faster rate than the materials of the 2D semiconductor nanostructures 66, the inner spacers 98, and the isolation structures 100. The etching may be isotropic. For example, when the first dummy nanostructures 64A are formed of silicon-germanium, the 2D semiconductor nanostructures 66 are formed of TMD, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the 2D semiconductor nanostructures 66 and expand the openings 128.

In FIGS. 8A-8B, gate dielectrics 132 are formed (e.g., conformally) around the nanostructures 66, such that the gate dielectrics 132 conformally line the recesses 126 and the openings 128. Specifically, the gate dielectric 132 is formed on the top surfaces of the fins 62; on the top surfaces, the sidewalls, and the bottom surfaces of the 2D semiconductor nanostructures 66; along sidewalls of the isolation structures 100; and along the sidewalls of the gate spacers 90. The gate dielectric 132 wraps around all (e.g., four) sides of the 2D semiconductor nanostructures 66. The gate dielectric layer 132 may also be formed on the sidewalls of the fins 62 (e.g., in embodiments where the top surfaces of the isolation regions 70 are below the top surfaces of the fins 62).

The gate dielectric 132 may include an oxide such as silicon oxide or a metal oxide, a silicate such as a metal silicate, combinations thereof, multi-layers thereof, or the like. The gate dielectric 132 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric 132 may include molecular-beam deposition (MBD), ALD, PECVD, and the like.

Next, a lower gate electrode 134L is formed in openings 128 below the isolation structures 100 to surround the lower 2D semiconductor nanostructures 66L, and an upper gate electrode 134U is formed in openings 128 above the isolation structures 100. In some embodiments, the lower gate electrode 134L and the upper gate electrode 134U each include one or more metal layers. For example, each of the lower gate electrode 134L and the upper gate electrode 134U may include one or more work function metal layers stacked one over another and a fill metal filling up a remainder of the openings 128. The one or more work function metal layers in the lower gate electrode 134L provide a suitable work function for the lower nanostructure-FET, and the one or more work function metal layers in the upper gate electrode 134U provide a suitable work function for the upper nanostructure-FET. For a p-type FET, the gate electrode 134L or 134U may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. For an n-type FET, the gate electrode 134L or 134U may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. In some embodiments, the fill metal in the lower gate electrode 134L and the upper gate electrode 134U may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. In some embodiments, the upper gate electrode 134U includes a different metal material than the lower gate electrode 134L.

In some embodiments, formation of the lower gate electrode 134L and upper gate electrode 134U comprises, for example, depositing one or more metal materials of the lower gate electrode 134L in the recesses 126 and the openings 128, etching back the one or more metal materials from the upper 2D semiconductor nanostructures 66U, forming one or more metal materials of the upper gate electrode 134U over the upper 2D semiconductor nanostructures 66U, followed by performing a CMP process on the metal materials of the upper gate electrode 134U and the gate dielectrics 132 until the second ILD 124 is exposed.

As illustrated in FIG. 8B, which is a cross-sectional view along a similar cross-section as reference cross-section C-C′ in FIG. 1A. The upper gate electrode 134U and the lower electrode 134L are also illustrated in FIG. 8B using dash lines to show the geometrical relationship among the gate electrodes 134U, 134L, the 2D semiconductor nanostructures 66U, 66L, and the epitaxial source/drain regions 108U, 108L. As illustrated in FIG. 8B, the upper gate electrode 134U and the lower gate electrode 134L in combination have a gate stack height H1 extending from a bottom surface of the lower gate electrode 134L to a top surface of the upper gate electrode 134U. Moreover, the 2D-CFET structure has a cell height H2 extending from one sidewall of the upper gate electrode 134U to another sidewall of the upper gate electrode 134U. In some embodiments, H1/H2 ratio (i.e., the ratio of gate stack height H1 to cell height H2) can be reduced, because the reduced thicknesses of 2D semiconductor nanostructures 66U, 66L allows for a reduced gate stack height H1. In some embodiments, the lower 2D semiconductor nanostructures 66L are separated by a distance greater than a thickness of each lower 2D semiconductor nanostructure 66L. For example, a ratio of the distance between the lower 2D semiconductor nanostructures 66L to a thickness of each lower 2D semiconductor nanostructure 66L is greater than 2:1, 3:1, 4:1, 5:1, 6:1, 7:1, 8:1, 9:1, or 10:1. In some embodiments, the upper 2D semiconductor nanostructures 66U are separated by a distance greater than a thickness of each upper 2D semiconductor nanostructure 66U. For example, a ratio of the distance between the upper 2D semiconductor nanostructures 66U to a thickness of each upper 2D semiconductor nanostructure 66U is greater than 2:1, 3:1, 4:1, 5:1, 6:1, 7:1, 8:1, 9:1, or 10:1.

FIGS. 8C-8E illustrate an example structure in subsequent processing after forming the gate electrodes 134, wherein FIG. 8C illustrate a cross-sectional view along a similar cross-section as reference cross-section A-A′ in FIG. 1A, FIGS. 8D and 8E illustrate cross-sectional views on different source/drain regions along a similar cross-section as reference cross-section C-C′ in FIG. 1A. In some embodiments, source/drain contacts are formed to make electrical contact with the source/drain regions 108U, 108L. For example, a first front-side source/drain contact 142 can be formed extending through the ILD 124 and the CESL 122 to the upper source/drain region 108U by etching a first front-side source/drain contact opening in the ILD 124 and the CESL 122 until the upper source/drain region 108U is exposed, followed by forming the first front-side source/drain contact 142 in the first front-side source/drain contact opening by depositing one or more metal materials in the first front-side source/drain contact opening and performing a CMP process to remove excessive metal materials outside the first front-side source/drain contact opening. In some embodiments, a second front-side source/drain contact 144 having a different depth than the first front-side source/drain contact 142 can be formed. Specifically, the second front-side source/drain contact 144 can be formed extending through the ILD 124, the CESL 122, the upper source/drain region 108U, the ILD 114, the CESL 112, to the lower source/drain region 108L by etching a second front-side source/drain contact opening through the ILD 124, the CESL 122, the upper source/drain region 108U, the ILD 114, the CESL 112, until the second lower source/drain region 108L is exposed, followed by forming the second front-side source/drain contact 144 in the second front-side source/drain contact opening by depositing one or more metal materials in the second front-side source/drain contact opening and performing a CMP process to remove excessive materials outside the second front-side source/drain contact opening. In some embodiments, a backside source/drain contact 146 is formed extending from a backside surface of the substrate 50 to a backside surface of a lower source/drain region 108L by, for example, etching a backside contact opening in the substrate 50 until the target lower source/drain region 108L is exposed, depositing one or more metal materials in the backside contact opening, followed by performing a CMP process to remove excessive metal materials outside the backside contact opening.

FIGS. 8C-8E further illustrate another CESL 152 deposited over the upper gate electrode 134U and another ILD 154 deposited over the CESL 152. In some embodiments, a gate contact 156 is formed extending through the ILD 154 and the CESL 152 to the upper gate electrode 134U, and source/drain vias 158 are formed extending through the ILD 154 and the CESL 152 to the front-side source/drain contacts 142 and 144. The gate contact 156 and the source/drain vias 158 can be formed by, for example, etching a plurality of openings in the ILD 154 and the CESL 152 until the upper gate electrode 134U and the front-side source/drain contacts 142, 144 are exposed, depositing one or more metal materials in these openings, followed by performing a CMP process to remove excessive metal materials outside the openings.

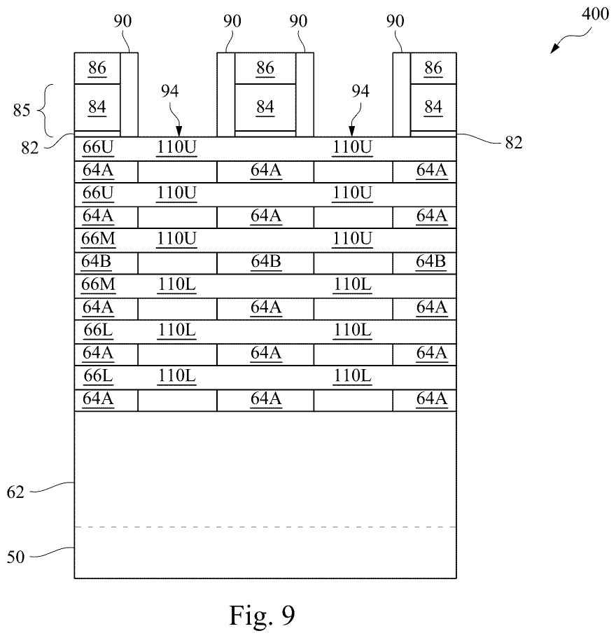

FIGS. 9-11 are cross-sectional views of a CFET device at various stages of manufacturing, in accordance with some other embodiments of the present disclosure. FIGS. 9-11 illustrate cross-sectional views along a similar cross-section as reference cross-section A-A′ in FIG. 1A. The structure illustrated in FIG. 9 is similar to that illustrated in FIG. 5, except that lower source/drain regions 110L are formed in the lower 2D semiconductor nanostructures 66L and a lower one of the middle semiconductor nanostructures 66M, and upper source/drain regions 110U are formed in the upper 2D semiconductor nanostructures 66 and an upper one of the middle semiconductor nanostructures 66M.

In some embodiments, the lower source/drain regions 110L are formed through an in-situ doping process concurrent with the deposition of the 2D semiconductor materials constituting the lower 2D semiconductor nanostructures 66L. This process ensures that the lower source/drain regions 110L are doped with either p-type or n-type dopant species. For instance, in embodiments where the lower 2D semiconductor nanostructures 66L are formed from WSe₂ layers, niobium (Nb) can be in-situ doped into the WSe₂ layers. During the deposition, Nb atoms substitute tungsten (W) atoms in the WSe₂ lattice, thereby creating holes that facilitate p-type conductivity. Conversely, in embodiments where the lower 2D semiconductor nanostructures 66L are formed from MoS₂ layers, rhenium (Re) can be in-situ doped into the MoS₂ layers. During the deposition, Re atoms substitute molybdenum (Mo) atoms in the MoS₂ lattice, providing additional electrons that contribute to n-type conductivity.

In some embodiments, the upper source/drain regions 110U are formed through an in-situ doping process concurrent with the deposition of the 2D semiconductor materials constituting the upper 2D semiconductor nanostructures 66U. This process ensures that the upper source/drain regions 110U are doped with either p-type or n-type dopants. For instance, in embodiments where the upper 2D semiconductor nanostructures 66U are formed from WSe₂ layers, niobium (Nb) can be in-situ doped into the WSe₂ layers. During the deposition, Nb atoms substitute tungsten (W) atoms in the WSe₂ lattice, thereby creating holes that facilitate p-type conductivity. Conversely, in embodiments where the upper 2D semiconductor nanostructures 66U are formed from MoS₂ layers, rhenium (Re) can be in-situ doped into the MoS₂ layers. During the deposition, Re atoms substitute molybdenum (Mo) atoms in the MoS₂ lattice, providing additional electrons that contribute to n-type conductivity. The conductivity type of the upper source/drain regions 110U may be opposite the conductivity type of the lower source/drain regions 110L. For example, the upper source/drain regions 110U may be oppositely doped from the lower epitaxial source/drain regions 110L.

In FIG. 9, the etching step for forming source/drain recesses 94 selectively etches the dummy nanostructures 64 but hardly attacks the 2D semiconductor nanostructures 66. Therefore, during forming the source/drain recesses 94, lower source/drain regions 110L remain substantially intact in the lower 2D semiconductor nanostructures 66L, and the upper source/drain regions 110U remain substantially intact in the upper 2D semiconductor nanostructure 66U.

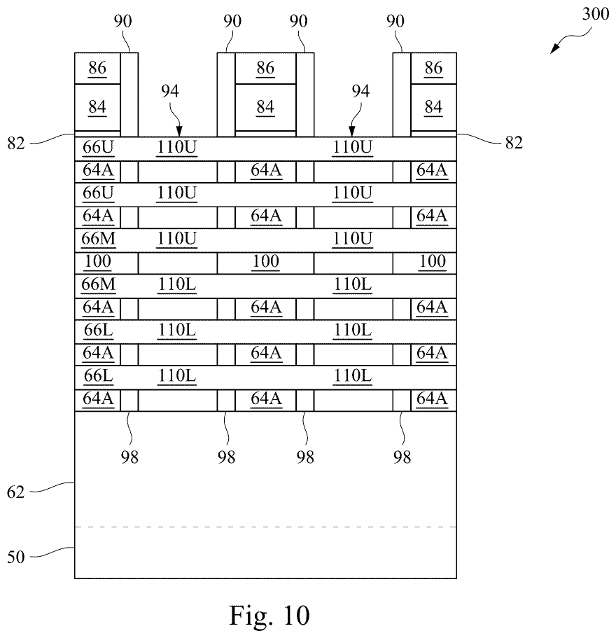

Next, in FIG. 10, inner spacers 98 and dielectric isolation layers 100 are formed. Forming inner spacers 98 and dielectric isolation layers 100 (also referred to as isolation structures 100) may include an etching process that laterally etches the dummy nanostructures 64A and removes the dummy nanostructure 64B. The etching process may be isotropic and may be selective to the material of the dummy nanostructures 64, so that the dummy nanostructures 64 are etched at a faster rate than the 2D semiconductor nanostructures 66. The etching process may also be selective to the material of the dummy nanostructures 64B, so that the dummy nanostructures 64B are etched at a faster rate than the dummy nanostructures 64A. In this manner, the dummy nanostructures 64B may be completely removed from between the middle 2D semiconductor nanostructures 66M without completely removing the dummy nanostructures 64A. In some embodiments where the dummy nanostructures 64B are formed of germanium or silicon germanium with a high germanium atomic percentage, the dummy nanostructures 64A are formed of silicon germanium with a low germanium atomic percentage, and the 2D semiconductor nanostructures 66 are formed of 2D semiconductor material (e.g., TMD) free from germanium, the etch process may comprise a dry etch process using chlorine gas, with or without a plasma. Because the dummy gate stacks 85 wrap around sidewalls of the 2D semiconductor nanostructures 66, the dummy gate stacks 85 may support the upper 2D semiconductor nanostructures 66U so that the upper 2D semiconductor nanostructures 66U do not collapse upon removal of the dummy nanostructures 64B. Further, although sidewalls of the dummy nanostructures 64A are illustrated as being straight after the etching, the sidewalls may be concave or convex. Inner spacers 98 are formed on sidewalls of the recessed dummy nanostructures 64A, and dielectric isolation layers 100 are formed between the middle 2D semiconductor nanostructures 66M.

The inner spacers 98 and the dielectric isolation layers 100 may be formed by conformally depositing an insulating material in the source/drain recesses 94, on sidewalls of the dummy nanostructures 64A, and between the middle 2D semiconductor nanostructures 66M, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 64A (thus forming the inner spacers 98) and has portions remaining in between the middle 2D semiconductor nanostructures 66M (thus forming the dielectric isolation layers 100).

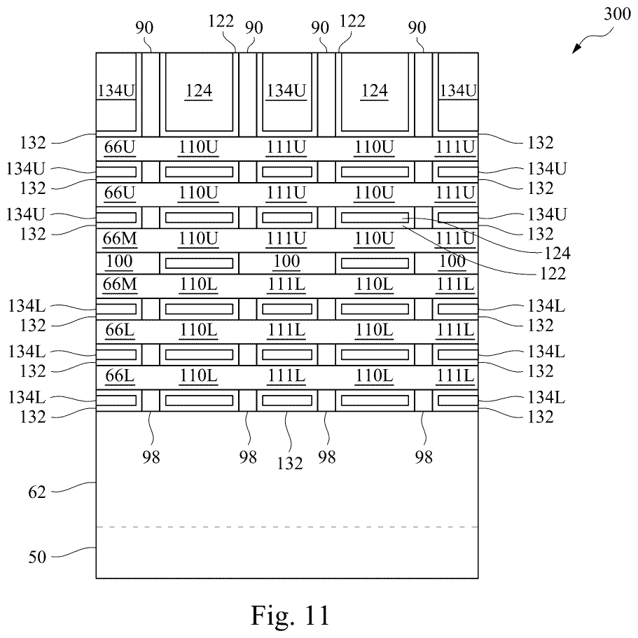

In FIG. 11, CESL 122 and ILD 124 are formed. The formation process may include depositing the layers for the CESL 122 and the ILD 124 into the source/drain recesses, and performing a planarization process to remove the excess portion of the corresponding layers. After the planarization process, top surfaces of the second ILD 124, the second CESL 122, and the gate spacers 90 are coplanar (within process variations).

Next, dummy gate stacks 85 are removed to form recesses (e.g., 126 as illustrated in FIG. 7) between gate spacers 90, followed by removing the first dummy nanostructures 64A to form openings (e.g., 128 as illustrated in FIG. 7) in regions between the 2D semiconductor nanostructures 66, followed by forming gate dielectric materials 132 in the recesses and openings to surround each of 2D semiconductor nanostructures 66, followed by forming a lower gate electrode 134L in openings below the isolation structures 100 to surround the lower 2D semiconductor nanostructures 66L, and an upper gate electrode 136U in openings above the isolation structures 100 to surround the upper 2D semiconductor nanostructures 66U. The resultant structure is illustrated in FIG. 11.

In FIG. 11, the lower 2D semiconductor nanostructures 66L each include channel regions 111L surrounded by different lower gate electrodes 134L, and source/drain regions 110L extending between adjacent two of the channel regions 111L. Similarly, the upper 2D semiconductor nanostructures 66U each include channel regions 111U surrounded by different upper gate electrode 134U, and source/drain regions 110U extending between adjacent two of the channel regions 111U. In some embodiments, the channel regions 111L of the lower 2D semiconductor nanostructures 66L may possess the same dopant as the lower source/drain regions 110L. This is due to the in-situ doping of the lower source/drain regions 110L during the deposition of the 2D semiconductor material, which results in the concurrent doping of the channel regions 111L. Similarly, in some embodiments, the channel regions 111U of the upper 2D semiconductor nanostructures 66U may possess the same dopant as the upper source/drain regions 110U. This is due to the in-situ doping of the upper source/drain regions 110U during the deposition of the 2D semiconductor material, which results in the concurrent doping of the channel regions 111U.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that CFETs formed using 2D semiconductor channel materials exhibit better gate control compared to silicon channels of the same dimensions, which allows for reduced gate lengths and widened sheet widths. Another advantage is that the thinner channel height of 2D semiconductor materials permits either an increased number of sheets at the same stack height or a reduced stack height with the same number of sheets. These advantages enable the 2D-CFETs to achieve an increased device density.

In some embodiments, a method includes following steps: forming a plurality of 2D semiconductor nanostructures (e.g., 66L and 66U) arranged one above another, each of the plurality of 2D semiconductor nanostructures having a 2D semiconductor material; forming first source/drain regions (e.g., 108L) at opposite regions of a first subset of the plurality of 2D semiconductor nanostructures; forming second source/drain regions (e.g., 108U) at opposite regions of a second subset of the plurality of 2D semiconductor nanostructures, the second source/drain regions being above the first source/drain regions; and forming a gate electrode (combination of 134L and 134U) over the plurality of 2D semiconductor nanostructures. In some embodiments, the 2D semiconductor material of the plurality of 2D semiconductor nanostructures comprises transition metal dichalcogenide (TMD). In some embodiments, forming the first source/drain regions (e.g., 108L) comprises growing a first doped 2D semiconductor material from the opposite regions of the first subset of the plurality of 2D semiconductor nanostructures. In some embodiments, forming the second source/drain regions (e.g., 108U) comprises growing a second doped 2D semiconductor material from the opposite regions of the second subset of the plurality of 2D semiconductor nanostructures. In some embodiments, the second doped 2D semiconductor material is of a conductivity type opposite a conductivity type of the first doped 2D semiconductor material. In some embodiments, a dopant species in the first doped 2D semiconductor material is different from a dopant species in the second doped 2D semiconductor material. In some embodiments, forming the gate electrode comprises forming a lower gate electrode (e.g., 134L) surrounding the first subset of the plurality of 2D semiconductor nanostructures, and forming an upper gate electrode (e.g., 134U) surrounding the second subset of the plurality of 2D semiconductor nanostructures. In some embodiments, the upper gate electrode and the lower gate electrode comprise different metal materials. In some embodiments, forming the first source/drain regions (e.g., 110L) comprises doping a first dopant species into the first subset of the plurality of 2D semiconductor nanostructures. In some embodiments, forming the second source/drain regions (e.g., 110U) comprises doping a second dopant species into the second subset of the plurality of 2D semiconductor nanostructures. In some embodiments, the second dopant species is different from the first dopant species.

In some embodiments, a method includes following steps: forming a p-type field effect transistor (PFET) over a substrate, the PFET comprising p-type source/drain regions (e.g., 108L), a plurality of PFET channel regions (e.g., 66L) vertically stacked over the substrate and laterally connecting the p-type source/drain regions, and a first gate electrode (e.g., 134L) surrounding the plurality of PFET channel regions; and forming an n-type field effect transistor (NFET) over the substrate, the NFET and the PFET being vertically stacked over the substrate, the NFET comprising n-type source/drain regions (e.g., 108U), a plurality of NFET channel regions (e.g., 66U) vertically stacked over the substrate and laterally connecting the n-type source/drain regions, and a second gate electrode (e.g., 134U) surrounding the plurality of NFET channel regions. One or more of the plurality of PFET channel regions and NFET channel regions comprise a 2D semiconductor material. In some embodiments, the p-type source/drain regions comprise a first doped 2D semiconductor material. In some embodiments, the n-type source/drain regions comprise a second doped 2D semiconductor material having a dopant species different from a dopant species of the first doped 2D semiconductor material. In some embodiments, the PFET channel regions are separated by a distance (e.g., T5) greater than a thickness (e.g., T4) of each of the plurality of PFET channel regions. In some embodiments, the NFET channel regions are separated by a distance (e.g., T5) greater than a thickness (e.g., T4) of each of the plurality of NFET channel regions.

In some embodiments, a device includes first 2D channel regions (e.g., 66L), second 2D channel regions (e.g., 66U), first source/drain regions (e.g., 108L), second source/drain regions (e.g., 108U), a lower gate electrode (e.g., 134L), and an upper gate electrode (e.g., 134U). The first 2D channel regions are over a substrate. Each of the first 2D channel regions includes a 2D semiconductor material. The second 2D channel regions are over the first 2D channel regions. Each of the second 2D channel regions includes a 2D semiconductor material. The first source/drain regions are at opposite sides of the first 2D channel regions. The second source/drain regions are at opposite sides of the second channel regions. The lower gate electrode surrounds the first 2D channel regions. The upper gate electrode is over the lower gate electrode and surrounds the second 2D channel regions. In some embodiments, the first 2D channel regions are vertically separated by a distance (e.g., T5) greater than a thickness (e.g., T4) of one of the first 2D channel regions. In some embodiments, the second 2D channel regions are vertically separated by a distance (e.g., T5) greater than a thickness (e.g., T4) of one of the second 2D channel regions. In some embodiments, the first source/drain regions and the second source/drain regions are of opposite conductivity types.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of 2D semiconductor nanostructures arranged one above another, each of the plurality of 2D semiconductor nanostructures having a 2D semiconductor material;
forming first source/drain regions at opposite regions of a first subset of the plurality of 2D semiconductor nanostructures;
forming second source/drain regions at opposite regions of a second subset of the plurality of 2D semiconductor nanostructures, the second source/drain regions being above the first source/drain regions; and
forming a gate electrode over the plurality of 2D semiconductor nanostructures.

2. The method of claim 1, wherein the 2D semiconductor material of the plurality of 2D semiconductor nanostructures comprises transition metal dichalcogenide (TMD).

3. The method of claim 1, wherein forming the first source/drain regions comprises growing a first doped 2D semiconductor material from the opposite regions of the first subset of the plurality of 2D semiconductor nanostructures.

4. The method of claim 3, wherein forming the second source/drain regions comprises growing a second doped 2D semiconductor material from the opposite regions of the second subset of the plurality of 2D semiconductor nanostructures.

5. The method of claim 4, wherein the second doped 2D semiconductor material is of a conductivity type opposite a conductivity type of the first doped 2D semiconductor material.

6. The method of claim 4, wherein a dopant species in the first doped 2D semiconductor material is different from a dopant species in the second doped 2D semiconductor material.

7. The method of claim 1, wherein forming the gate electrode comprises forming a lower gate electrode surrounding the first subset of the plurality of 2D semiconductor nanostructures, and forming an upper gate electrode surrounding the second subset of the plurality of 2D semiconductor nanostructures.

8. The method of claim 7, wherein the upper gate electrode and the lower gate electrode comprise different metal materials.

9. The method of claim 1, wherein forming the first source/drain regions comprises doping a first dopant species into the first subset of the plurality of 2D semiconductor nanostructures.

10. The method of claim 9, wherein forming the second source/drain regions comprises doping a second dopant species into the second subset of the plurality of 2D semiconductor nanostructures.

11. The method of claim 10, wherein the second dopant species is different from the first dopant species.

12. A method, comprising:
forming a p-type field effect transistor (PFET) over a substrate, the PFET comprising p-type source/drain regions, a plurality of PFET channel regions vertically stacked over the substrate and laterally connecting the p-type source/drain regions, and a first gate electrode surrounding the plurality of PFET channel regions; and
forming an n-type field effect transistor (NFET) over the substrate, the NFET and the PFET being vertically stacked over the substrate, the NFET comprising n-type source/drain regions, a plurality of NFET channel regions vertically stacked over the substrate and laterally connecting the n-type source/drain regions, and a second gate electrode surrounding the plurality of NFET channel regions,
wherein one or more of the plurality of PFET channel regions and NFET channel regions comprise a 2D semiconductor material.

13. The method of claim 12, wherein the p-type source/drain regions comprise a first doped 2D semiconductor material.

14. The method of claim 13, wherein the n-type source/drain regions comprise a second doped 2D semiconductor material having a dopant species different from a dopant species of the first doped 2D semiconductor material.

15. The method of claim 12 wherein the plurality of PFET channel regions are separated by a distance greater than a thickness of each of the plurality of PFET channel regions.

16. The method of claim 12, wherein the plurality of NFET channel regions are separated by a distance greater than a thickness of each of the plurality of NFET channel regions.

17. A device, comprising:
first 2D channel regions over a substrate, each of the first 2D channel regions comprising a 2D semiconductor material;
second 2D channel regions over the first 2D channel regions, each of the second 2D channel regions comprising a 2D semiconductor material;
first source/drain regions at opposite sides of the first 2D channel regions;
second source/drain regions at opposite sides of the second 2D channel regions;
a lower gate electrode surrounding the first 2D channel regions; and
an upper gate electrode over the lower gate electrode and surrounding the second 2D channel regions.

18. The device of claim 17, wherein the first 2D channel regions are vertically separated by a distance greater than a thickness of one of the first 2D channel regions.

19. The device of claim 17, wherein the second 2D channel regions are vertically separated by a distance greater than a thickness of one of the second 2D channel regions.

20. The device of claim 17, wherein the first source/drain regions and the second source/drain regions are of opposite conductivity types.
